(19) United States
(12) Patent Application Publication
(10) Pub. No.: US 2026/0206341 A1
(43) Pub. Date: Jul. 16, 2026

(54) SENSOR PACKAGE STRUCTURE AND MANUFACTURING METHOD THEREOF

(71) Applicant: TONG HSING ELECTRONIC INDUSTRIES, LTD., Taoyuan City (TW)

(72) Inventors: TIEN-HAO CHENG, Taoyuan City (TW); Cheng-Chang Wu, Taoyuan City (TW); LI-CHUN HUNG, Taoyuan City (TW)

(21) Appl. No.: 19/188,025

(22) Filed: Apr. 24, 2025

(30) Foreign Application Priority Data
Jan. 10, 2025 (TW) 114101009

(51) Int. Cl. H10F 39/00

(52) U.S. Cl. CPC H10F 39/804; H10F 39/8057; H10F 39/811

(57) ABSTRACT

A manufacturing method of a sensor package structure includes: mounting a sensor chip onto a circuit board and using a plurality of metal wires to connect the sensor chip and the circuit board in a wire-bonding manner, in which each of the metal wires has an outer end portion connected to the circuit board; forming a ring-shaped adhesive layer on the circuit board along the outer end portions of the metal wires, such that the outer end portions of the metal wires are embedded in the adhesive layer; adhering a cap onto the adhesive layer and solidifying the adhesive layer, in which a bottom side of the cap is sunk into and adhered to the adhesive layer; and forming an encapsulant on the circuit board, in which the encapsulant covers a surrounding lateral surface of the cap.

### CROSS-REFERENCE TO RELATED PATENT APPLICATION

This application claims the benefit of priority to Taiwan Patent Application No. 114101009, filed on January 10, 2025. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure and a manufacturing method thereof.

### BACKGROUND OF THE DISCLODERE

A conventional sensor package structure needs to meet miniaturization requirements, such that an overall quality of the conventional sensor package structure is possibly affected. For example, when each of metal wires of the conventional sensor package structure is at least partially embedded in an encapsulant, an adhesive layer needs to be formed on a sensor chip, such that the adhesive layer easily flows to a sensing region of the sensor chip, thereby causing contamination. However, when the metal wires of the conventional sensor package structure are not embedded in the encapsulant, an overall size of the conventional sensor package structure is too large to meet the miniaturization requirements.

### SUMMARY OF THE DISCLOSURENT

In response to the above-referenced technical inadequacies, the present disclosure provides a sensor package structure and a manufacturing method thereof for effectively improving on the issues associated with conventional sensor package structures.

In order to solve the above-mentioned problems, one of the technical aspects adopted by the present disclosure is to provide a manufacturing method of a sensor package structure, which includes: a preparation step, an adhesive arrangement step, a placing step, and an encapsulating step. The preparation step is implemented by mounting a sensor chip onto a circuit board and wire-bonding the sensor chip and the circuit board through a plurality of metal wires. Each of the metal wires has an outer end portion connected to the circuit board and an inner end portion that is connected to the sensor chip. The adhesive arrangement step is implemented by forming an adhesive layer on the circuit board along the outer end portions of the metal wires. The adhesive layer is ring-shaped and has a protecting segment and a carrying segment that surrounds the protecting segment. The outer end portions of the metal wires are embedded in the protecting segment. The placing step is implemented by bonding a cap to the carrying segment and solidifying the adhesive layer. The cap includes a light-permeable layer and an opaque stand. The light-permeable layer has a light-permeable region facing toward the sensor chip and a distribution region that surrounds the light-permeable region. The opaque stand has a top side that is fixed to the distribution region of the light-permeable layer. A bottom side of the opaque stand is sunk into and adhered to the carrying segment of the adhesive layer. The encapsulating step is implemented by forming an encapsulant on the circuit board, and the encapsulant covers a surrounding lateral surface of the cap.

In order to solve the above-mentioned problems, another one of the technical aspects adopted by the present disclosure is to provide a sensor package structure, which includes a circuit board, a sensor chip, a plurality of metal wires, an adhesive layer, a cap, and an encapsulant. The circuit board has a first surface and a second surface that is opposite to the first surface. The circuit board includes a plurality of bonding pads arranged on the first surface. The sensor chip is mounted on the first surface of the circuit board. A top surface of the sensor chip has a sensing region and a plurality of connection pads that are arranged outside of the sensing region. Each of the metal wires has an outer end portion and an inner end portion. The outer end portions of the metal wires are respectively connected to the bonding pads of the circuit boards, and the inner end portions of the metal wires are respectively connected to the connection pads of the sensor chip. The adhesive layer is ring-shaped and is disposed on the first surface of the circuit board along the outer end portions of the metal wires. The adhesive layer includes a protecting segment and a carrying segment that surrounds the protecting segment. The outer end portions of the metal wires are embedded in the protecting segment. The cap is adhered to the carrying segment of the adhesive layer. The cap, the circuit board, and the adhesive layer jointly define an enclosed space. The cap includes a light-permeable layer and an opaque stand. The light-permeable layer has a light-permeable region facing toward the sensing region and a distribution region that surrounds the light-permeable region. The opaque stand has a top side that is fixed to the distribution region of the light-permeable layer. A bottom side of the opaque stand is sunk into and adhered to the carrying segment of the adhesive layer. The encapsulant is formed on the first surface of the circuit board. The cap and the adhesive layer are embedded in the encapsulant, and an outer surface of the light-permeable layer is at least partially exposed from the encapsulant.

Therefore, the sensor package structure and the manufacturing method thereof in the present disclosure are provided by using a viscosity of the adhesive layer for enabling the adhesive layer to be in suitable structural cooperation with the metal wires and the cap, thereby effectively reducing an overall size of the sensor package structure. Accordingly, the sensor packaging structure provided by the present disclosure can meet the requirements of miniaturization and can prevent the sensor chip from being contaminated by any adhesive.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic perspective view of a sensor package structure according to one embodiment of the present disclosure;

FIG. 2 is a schematic top view of FIG. 1 when an encapsulant is omitted;

FIG. 3 is a schematic cross-sectional view taken along line III-III of FIG. 1;

FIG. 4 is a schematic cross-sectional view showing a first variation of the configuration of the sensor package structure shown in FIG. 3;

FIG. 5 is a schematic cross-sectional view showing a second variation of the configuration of the sensor package structure shown in FIG. 3;

FIG. 6 is a schematic cross-sectional view showing a third variation of the configuration of the sensor package structure shown in FIG. 3;

FIG. 7 is a schematic cross-sectional view showing a preparation step of a manufacturing method of the sensor package structure according to the present disclosure;

FIG. 8 is a schematic cross-sectional view showing an adhesive arrangement step of the manufacturing method of the sensor package structure according to the present disclosure;

FIG. 9 is a schematic cross-sectional view showing a placing step of the manufacturing method of the sensor package structure according to the present disclosure; and

FIG. 10 is a schematic cross-sectional view showing the placing step of the manufacturing method of the sensor package structure according to the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

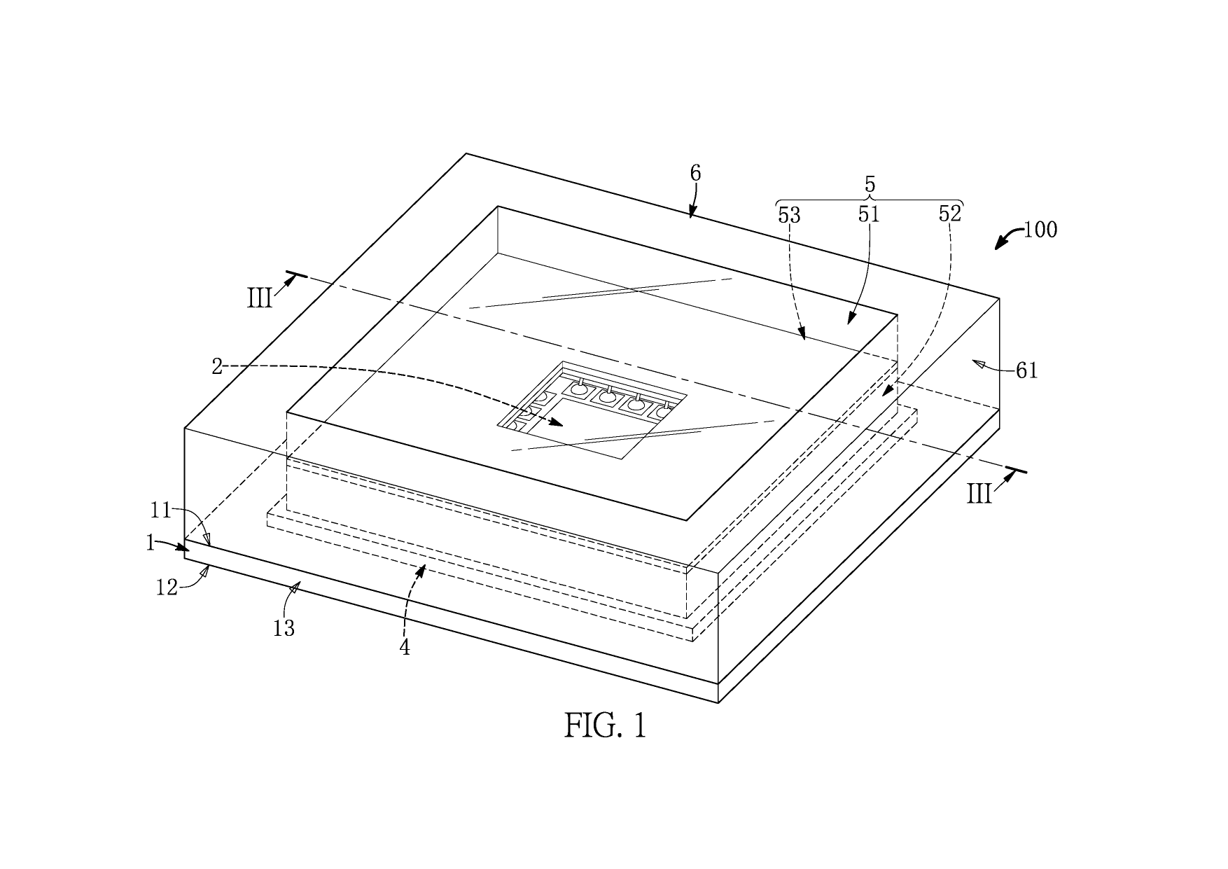

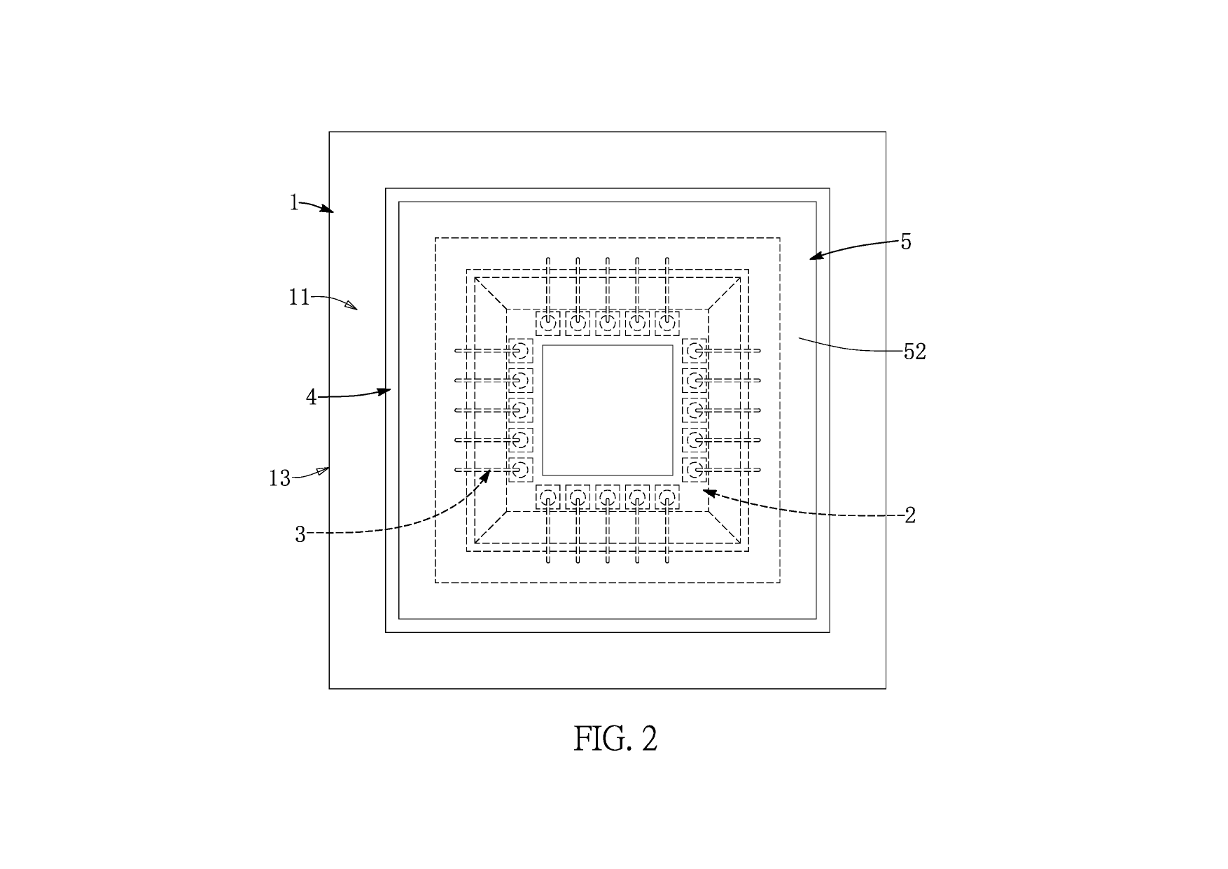

Referring to FIG. 1 to FIG. 10, an embodiment of the present disclosure provides a sensor package structure 100 and a manufacturing method thereof. The sensor package structure 100 in the present embodiment can be manufactured by implementing the manufacturing method provided by the present embodiment, but the present disclosure is not limited thereto. For example, in other embodiments of the present disclosure not shown in the drawings, the sensor package structure 100 can be manufactured by implementing a method other than the manufacturing method of the present embodiment. In addition, in order to clearly describe the present embodiment, the following description describes the sensor package structure 100, and then describes the manufacturing method.

### Sensor Package Structure

As shown in FIG. 1 to FIG. 3 of the present embodiment, the sensor package structure 100 includes a circuit board 1, a sensor chip 2 mounted on the circuit board 1, a plurality of metal wires 3 electrically coupled to the circuit board 1 and the sensor chip 2, an adhesive layer 4 being ring-shaped and being disposed on the circuit board 1 along the metal wires 3, a cap 5 adhered to the adhesive layer 4, and an encapsulant 6 that is formed on the circuit board 1.

The circuit board 1 of the present embodiment has a square shape or a rectangular shape, but the present disclosure is not limited thereto. The circuit board 1 has a first surface 11 and a second surface 12 that is opposite to the first surface 11. The first surface 11 of the circuit board 1 includes a chip-bonding region 111 arranged approximately on a center portion thereof, and the circuit board 1 includes a plurality of bonding pads 112 that are disposed on the first surface 11 and that are arranged outside of the chip-bonding region 111. The bonding pads 112 in the present embodiment are in an annular arrangement, but the present disclosure is not limited thereto. For example, in other embodiments of the present disclosure not shown in the drawings, the bonding pads 112 can be arranged in two rows respectively at two opposite sides of the chip-bonding region 111.

In addition, the circuit board 1 can be further provided with a plurality of solder balls 7 disposed on the second surface 12 thereof. The circuit board 1 can be soldered onto an electronic component (not shown in the drawings) through the solder balls 7, thereby electrically connecting the sensor package structure 100 to the electronic component.

The sensor chip 2 in the present embodiment is an image sensing chip, but the present disclosure is not limited thereto. The sensor chip 2 is fixed onto the first surface 11 of the circuit board 1 (e.g., the chip-bonding region 111) through a bottom surface 22 thereof. In other words, the sensor chip 2 is arranged to be surrounded on the inside of the bonding pads 112. It should be noted that the sensor package structure 100 in the present embodiment includes an adhesive (not labeled in the drawings) disposed on the chip-bonding region 111, and the sensor chip 2 is fixed onto the chip-bonding region 111 through the adhesive, but the present disclosure is not limited thereto. For example, in other embodiments of the present disclosure not shown in the drawings, the adhesive can be omitted or can be replaced by other components.

Specifically, a top surface 21 of the sensor chip 2 has a sensing region 211 and a plurality of connection pads 212 that are arranged outside of the sensing region 211. Moreover, the number and positions of the connection pads 212 of the sensor chip 2 in the present embodiment correspond to those of the bonding pads 112 of the circuit board 1. In other words, the connection pads 212 are substantially in an annular arrangement, and a quantity of the connection pads 212 is equal to a quantity of the bonding pads 112.

Each of the metal wires 3 has an outer end portion 31 and an inner end portion 32. The outer end portions 31 of the metal wires 3 are respectively connected to the bonding pads 112 of the circuit boards 1, and the inner end portions 32 of the metal wires 3 are respectively connected to the connection pads 212 of the sensor chip 2, such that the circuit board 1 is electrically coupled to the sensor chip 2 through the metal wires 3. Any one of the metal wires 3 can be configured in a normal wire-bonding manner or a reverse wire-bonding manner according to design requirements, and the present disclosure is not limited thereto.

The adhesive layer 4 has a rectangular ring shape and is disposed on the first surface 11 of the circuit board 1 along the outer end portions 31 of the metal wires 3. The adhesive layer 4 in the present embodiment is formed by being arranged on the circuit board 1 in a dispensing manner and then being solidified, a height of the adhesive layer 4 with respect to the circuit board 1 is lower than a height of the sensor chip 2 with respect to the circuit board 1, and the adhesive layer 4 is not in contact with the sensor chip 2, but the present disclosure is not limited thereto. For example, in other embodiments of the present disclosure not shown in the drawings, the height of the adhesive layer 4 can be equal to or slightly higher than the height of the sensor chip 2 according to practical requirements.

Specifically, the adhesive layer 4 in the present embodiment has a protecting segment 41, a carrying segment 42 connected to the protecting segment 41, and an outer segment 43 that is ring-shaped and that is connected to the carrying segment 42, but the present disclosure is not limited thereto. For example, in other embodiments of the present disclosure not shown in the drawings, the outer segment 43 can be omitted according to practical requirements.

The protecting segment 41 is ring-shaped, and the outer end portions 31 of the metal wires 3 are embedded in the protecting segment 41. The carrying segment 42 is ring-shaped and surrounds the protecting segment 41, and the outer segment 43 surrounds the carrying segment 42. In other words, the carrying segment 42 is arranged between the protecting segment 41 and the outer segment 43. Moreover, a thickness T42 of the carrying segment 42 is less than a thickness T41 of the protecting segment 41 and is less than a thickness T43 of the outer segment 43, and the thickness T41 of the protecting segment 41 can be equal to or slightly greater than the thickness T43 of the outer segment 43. In other words, the adhesive layer 4 has a ring-shaped slot recessed in a top side of the carrying segment 42.

It should be noted that the outer end portion 31 of each of the metal wires 3 in the present embodiment is limited to being embedded in the protecting segment 41 of the adhesive layer 4, thereby protecting the outer end portion 31 and achieving a miniaturization of the sensor package structure 100. In other words, any package structure, provided with metal wires that are not embedded in adhesive, is different from the sensor package structure 100 provided by the present embodiment.

The cap 5 is adhered to the carrying segment 42 of the adhesive layer 4, and the cap 5, the circuit board 1, and the adhesive layer 4 jointly define an enclosed space E that receives the sensor chip 2 and a part of each of the metal wires 3 therein. It should be noted that the cap 5 in the present embodiment is fixed to the adhesive layer 4 through a viscosity of the adhesive layer 4, so that the cap 5 and the adhesive layer 4 are provided without another adhesive therebetween.

In the present embodiment, the cap 5 includes a light-permeable layer 51, an opaque stand 52 fixed to the light-permeable layer 51, and a bonding layer 53 that is adhered to and connects the light-permeable layer 51 and the opaque stand 52. The light-permeable layer 51 in the present embodiment is a transparent and flat glass board, and the light-permeable layer 51 has a light-permeable region 511 facing toward the sensing region 211 and a distribution region 512 that is ring-shaped and that surrounds the light-permeable region 511. A top side 521 of the opaque stand 52 is fixed to the distribution region 512 of the light-permeable layer 51 (through the bonding layer 53), a bottom side 522 of the opaque stand 52 is sunk into and adhered to the carrying segment 42 of the adhesive layer 4, the outer segment 43 protrudes from the opaque stand 52.

Moreover, the opaque stand 52 in the present embodiment is integrally formed as a single one-piece structure, and the opaque stand 52 includes shielding board 523 and a ring-shaped frame 524 that is connected to the shielding board 523. The shielding board 523 has the top side 521 of the opaque stand 52, the bonding layer 53 is sandwiched between and adhered to the distribution region 512 of the light-permeable layer 51 and the shielding board 523 of the opaque stand 52, and the ring-shaped frame 524 is connected to a peripheral portion of the shielding board 523 and has the bottom side 522 of the opaque stand 52.

Specifically, the metal wires 3 are arranged in a projection space that is defined by orthogonally projecting the shielding board 523 onto the circuit board 1, such that the opaque stand 52 can be provided to effectively prevent the sensor package structure 100 from occurring a flare issue generated from the metal wires 3.

In other words, the light-permeable region 511 can be referred to as a portion of the light-permeable layer 51 not covered by the shielding board 523, and the light-permeable region 511 faces toward the sensing region 211 of the sensor chip 2. In other words, a projection region defined by orthogonally projecting the light-permeable region 511 onto the top surface 21 of the sensor chip 2 covers an entirety of the sensing region 211 and does not cover any one of the connection pads 212 (and any one of the metal wires 3).

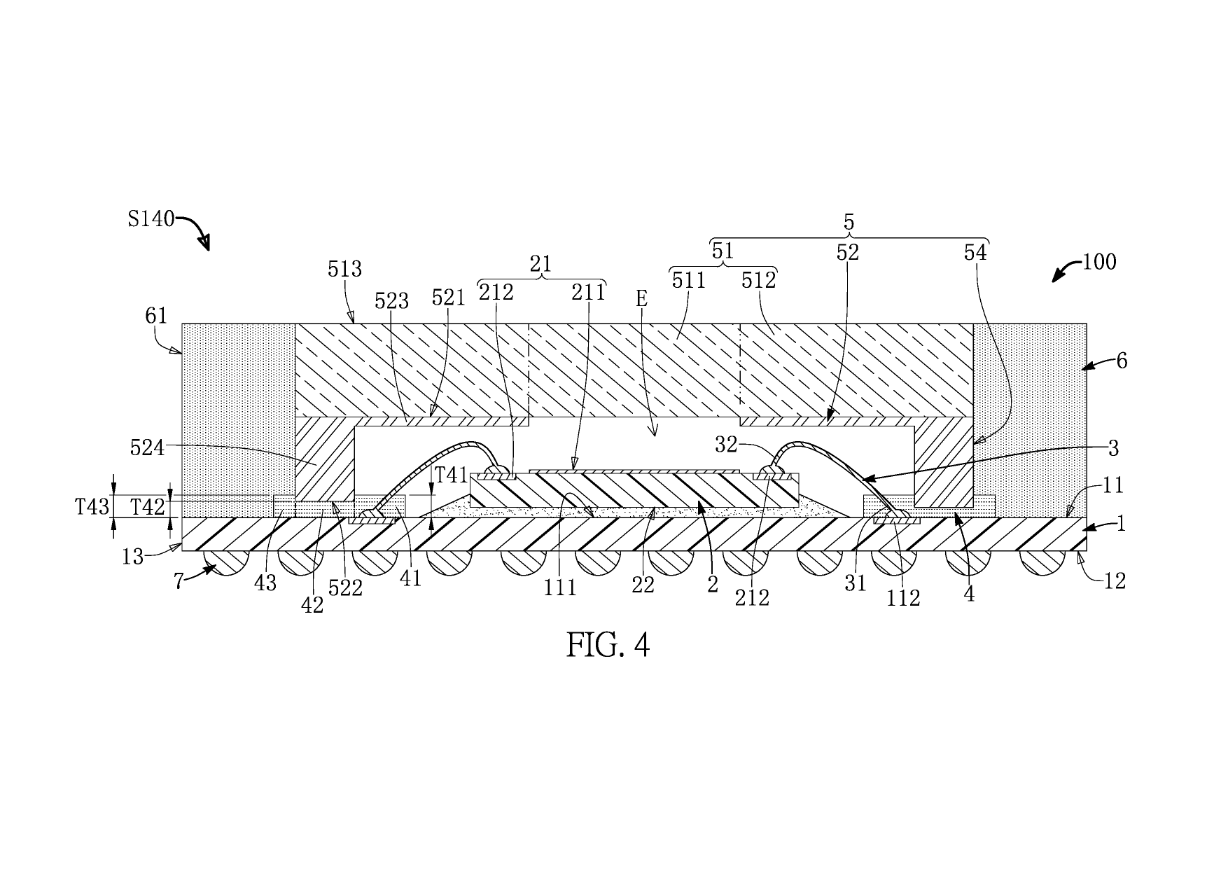

It should be noted that the light-permeable layer 51 and the opaque stand 52 shown in FIG. 1 to FIG. 3 of the present embodiment are adhered to and fixed to each other through the bonding layer 53, but the present disclosure is not limited thereto. For example, as shown in FIG. 4 to FIG. 6, the opaque stand 52 can be formed on the distribution region 412 of the light-permeable layer 51 in an injection molding manner so as to be jointly formed as the cap 5; or, in other embodiments of the present disclosure not shown in the drawings, the light-permeable layer 51 and the opaque stand 52 can be fixed to each other in other manners that are different from the bonding layer 53.

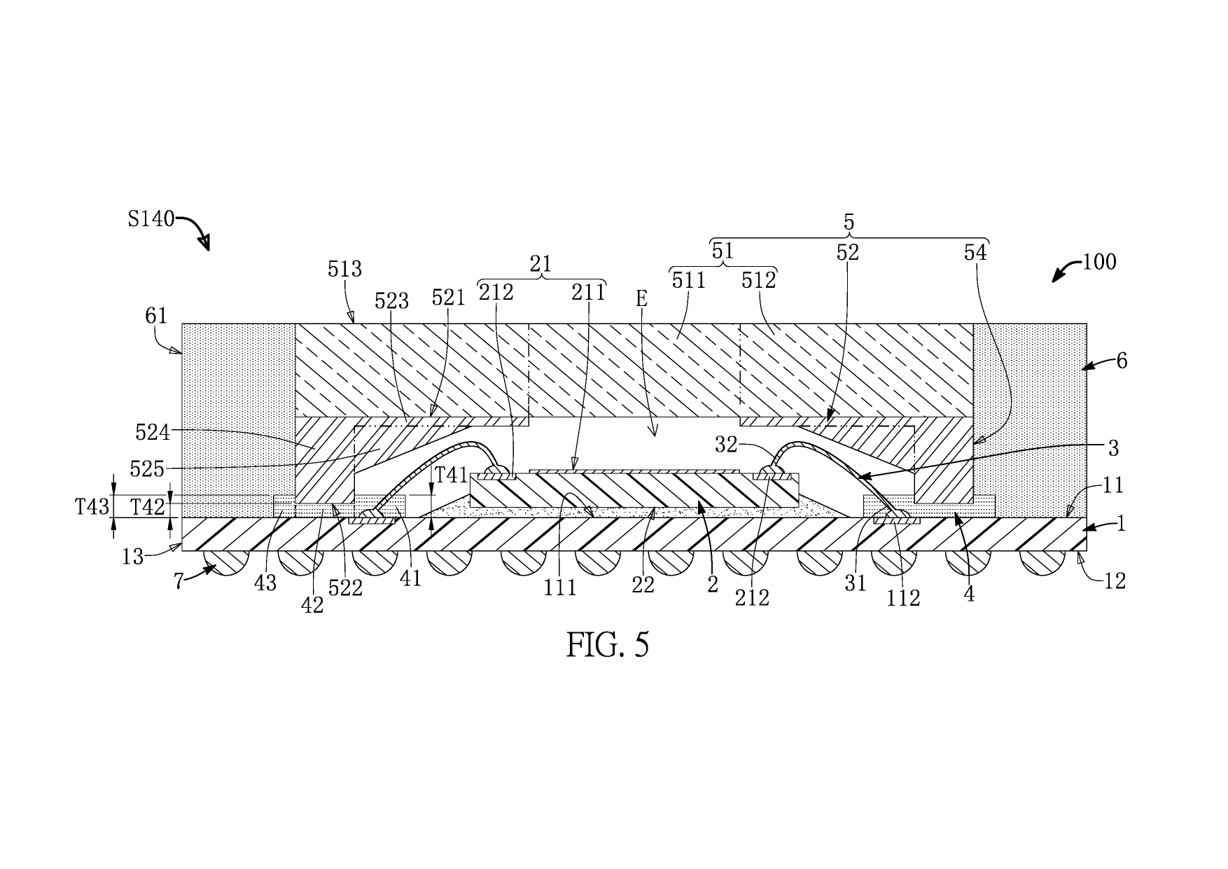

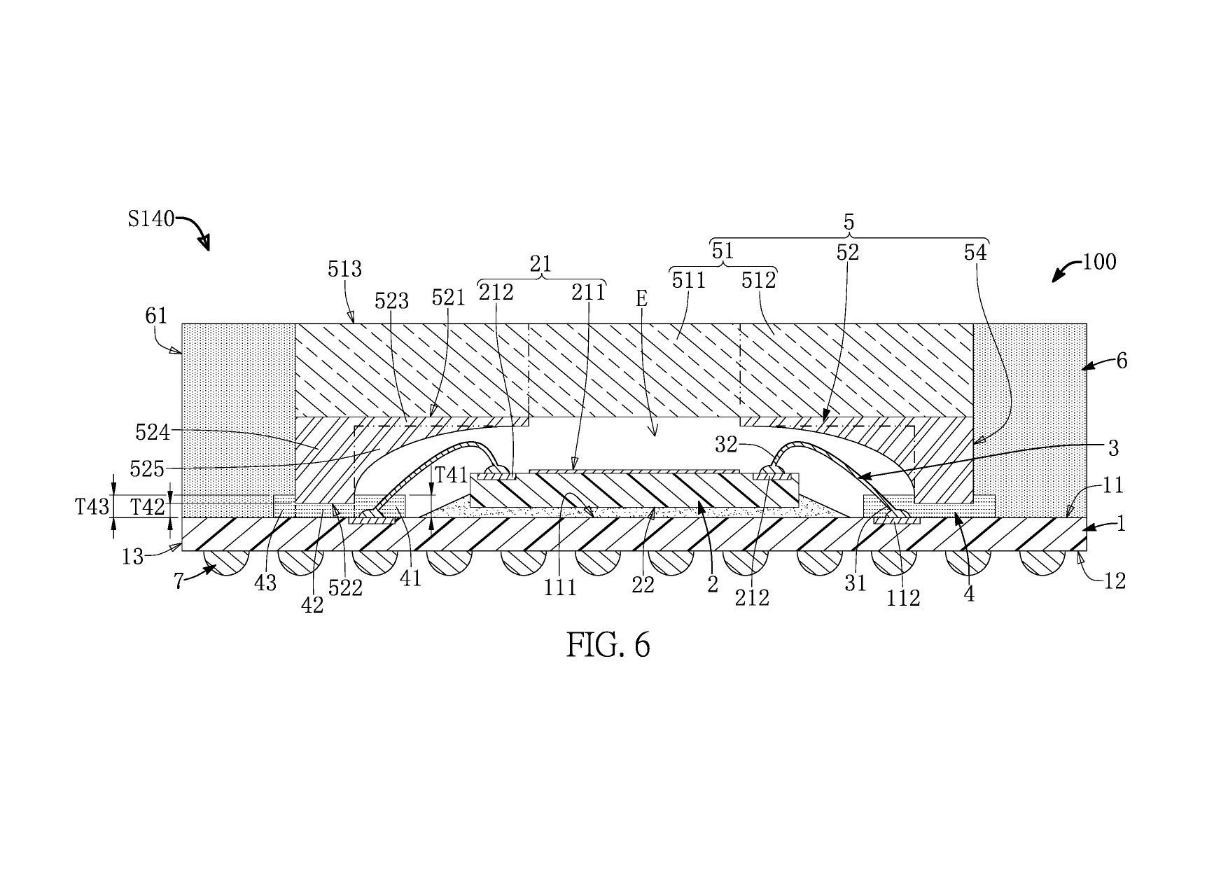

Specifically, as shown in FIG. 5 and FIG. 6, the opaque stand 52 can further include a structural reinforcement portion 525 that is connected to the shielding board 523 and the ring-shaped frame 524. The structural reinforcement portion 525 can be ring-shaped or can include a plurality of ribs, and the structural reinforcement portion 525 is arranged inside of the shielding board 523 and the ring-shaped frame 524, thereby effectively improving a stress concentration issue that occurs at a connection between the shielding board 523 and the ring-shaped frame 524.

As shown in FIG. 1 to FIG. 3, the encapsulant 6 is formed on the first surface 11 of the circuit board 1, the cap 5 and the adhesive layer 4 (e.g., the outer segment 43) are embedded in the encapsulant 6, and an outer surface 513 of the light-permeable layer 51 is at least partially exposed from the encapsulant 6. Moreover, a surrounding lateral surface 61 of the encapsulant 6 is preferably flush with lateral edges 13 of the circuit board 1, but the present disclosure is not limited thereto.

In addition, the encapsulant 6 in the present embodiment is a molding compound, but the present disclosure is not limited thereto. For example, in other embodiments of the present disclosure not shown in the drawings, the encapsulant 6 can be a solidified liquid compound according to practical requirements; or, the encapsulant 6 can include a solidified liquid compound and a molding compound that is formed on a top surface of the solidified liquid compound.

In summary, the sensor package structure 100 in the present embodiment is formed by using the viscosity of the adhesive layer 4 for enabling the adhesive layer 4 to be in suitable structural cooperation with the metal wires 3 and the cap 5, thereby effectively reducing an overall size of the sensor package structure 100. Accordingly, the sensor packaging structure 100 provided by the present embodiment can meet the requirements of miniaturization and can prevent the sensor chip 2 from being contaminated by adhesives.

In addition, in the sensor package structure 100 provided by the present embodiment, the bottom side 522 of the opaque stand 52 is sunk into the adhesive layer 4, so that when different portions of the bottom side 522 of the opaque stand 52 have a slight difference in height, the adhesive layer 4 can be configured to absorb the difference (e.g., as shown in FIG. 4, the different portions of the bottom side 522 being embedded in the adhesive layer 4 by different depths), thereby enabling the shielding board 523 to provide a better levelness.

### Manufacturing Method of Sensor Package Structure

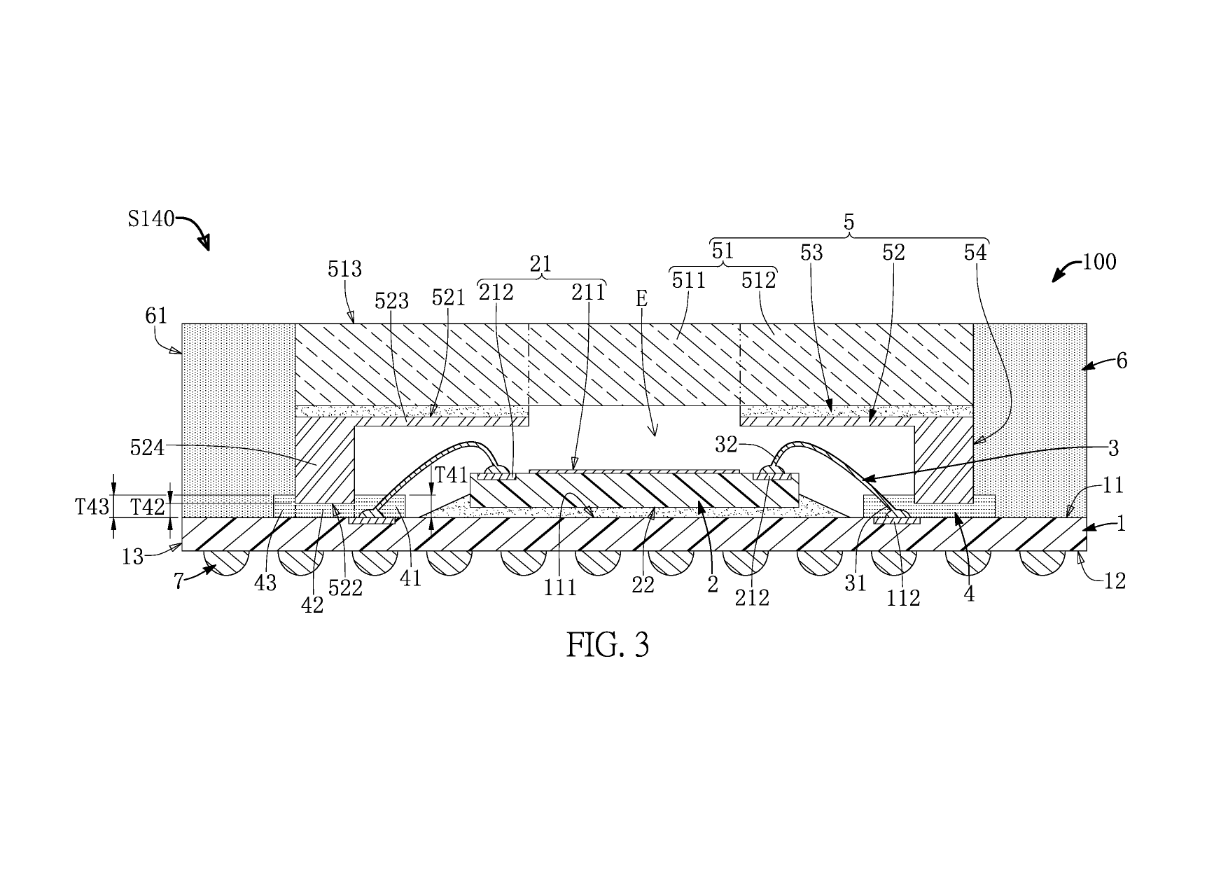

As shown in FIG. 3 and FIG. 7 to FIG. 10, the manufacturing method in the present embodiment includes (or implements): a preparation step S110, an adhesive arrangement step S120, a placing step S130, and an encapsulating step S140. It should be noted that the sensor package structure 100 described in the above description of the present embodiment can be manufactured by implementing the above steps S110 - S140 of the manufacturing method, so that the manufacturing method can refer to the above description of the sensor package structure 100. The following description substantially describes each of the steps S110 - S140 of the manufacturing method, but the present disclosure is not limited thereto.

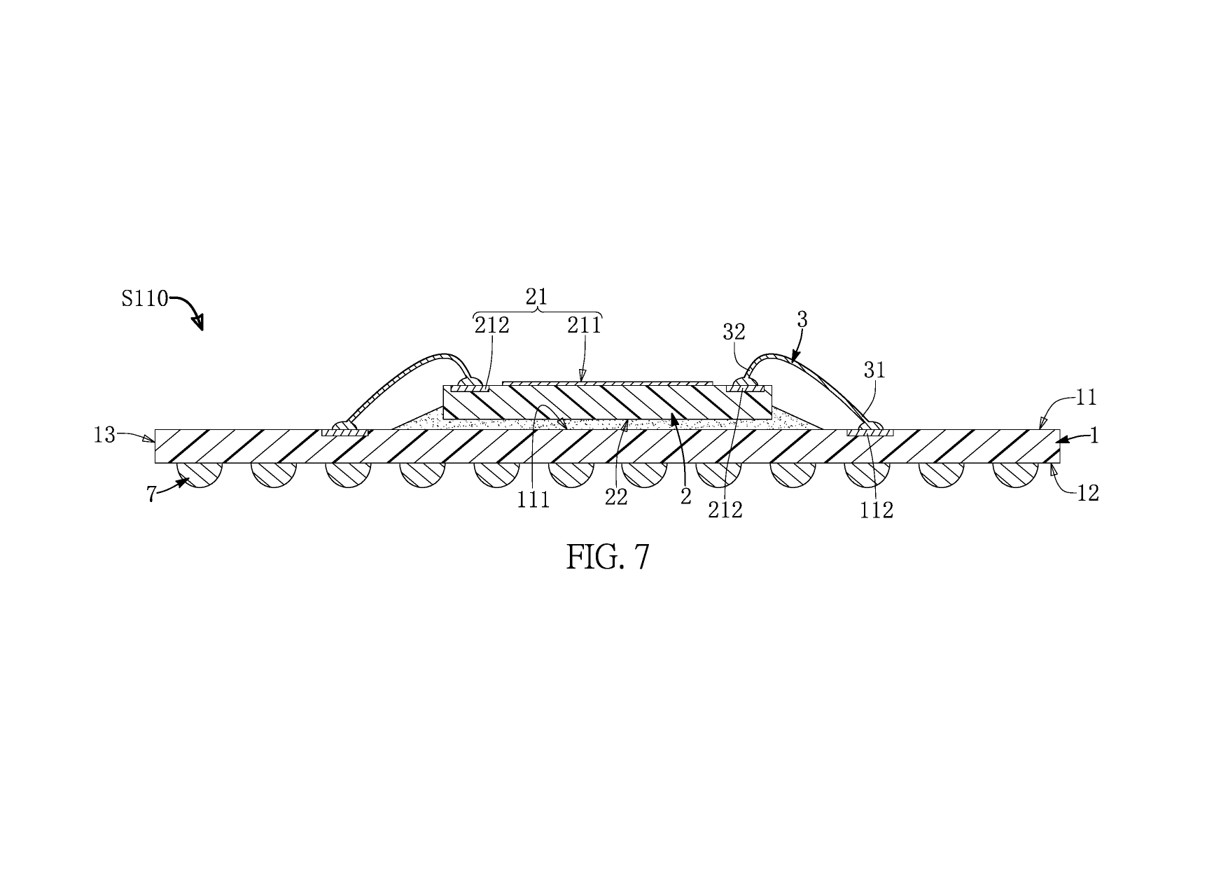

As shown in FIG. 7, the preparation step S110 is implemented by mounting a sensor chip 2 onto a circuit board 1, and wire-bonding the sensor chip 2 and the circuit board 1 through a plurality of metal wires 3. Specifically, each of the metal wires 3 has an outer end portion 31 connected to the circuit board 1 and an inner end portion 32 that is connected to the sensor chip 2.

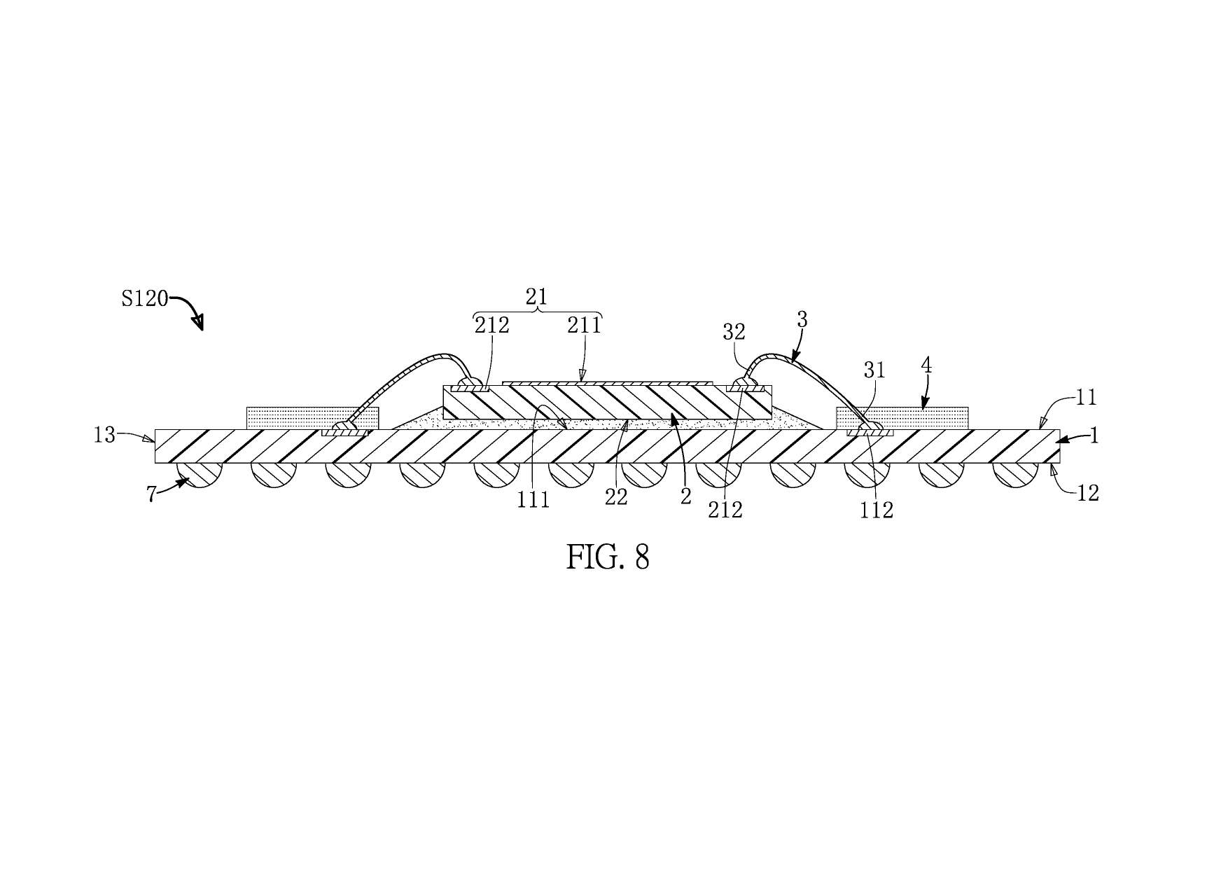

As shown in FIG. 8, the adhesive arrangement step S120 is implemented by forming an adhesive layer 4 on the circuit board 1 along the outer end portions 31 of the metal wires 3. Specifically, the adhesive layer 4 is ring-shaped and has a protecting segment 41, a carrying segment 42 that surrounds the protecting segment 41, and an outer segment 43 that is ring-shaped and that surrounds the carrying segment 42. Moreover, the outer end portions 31 of the metal wires 3 are embedded in the protecting segment 41, a height of the adhesive layer 4 with respect to the circuit board 1 is lower than a height of the sensor chip 2 with respect to the circuit board 1, and the adhesive layer 4 is not in contact with the sensor chip 2.

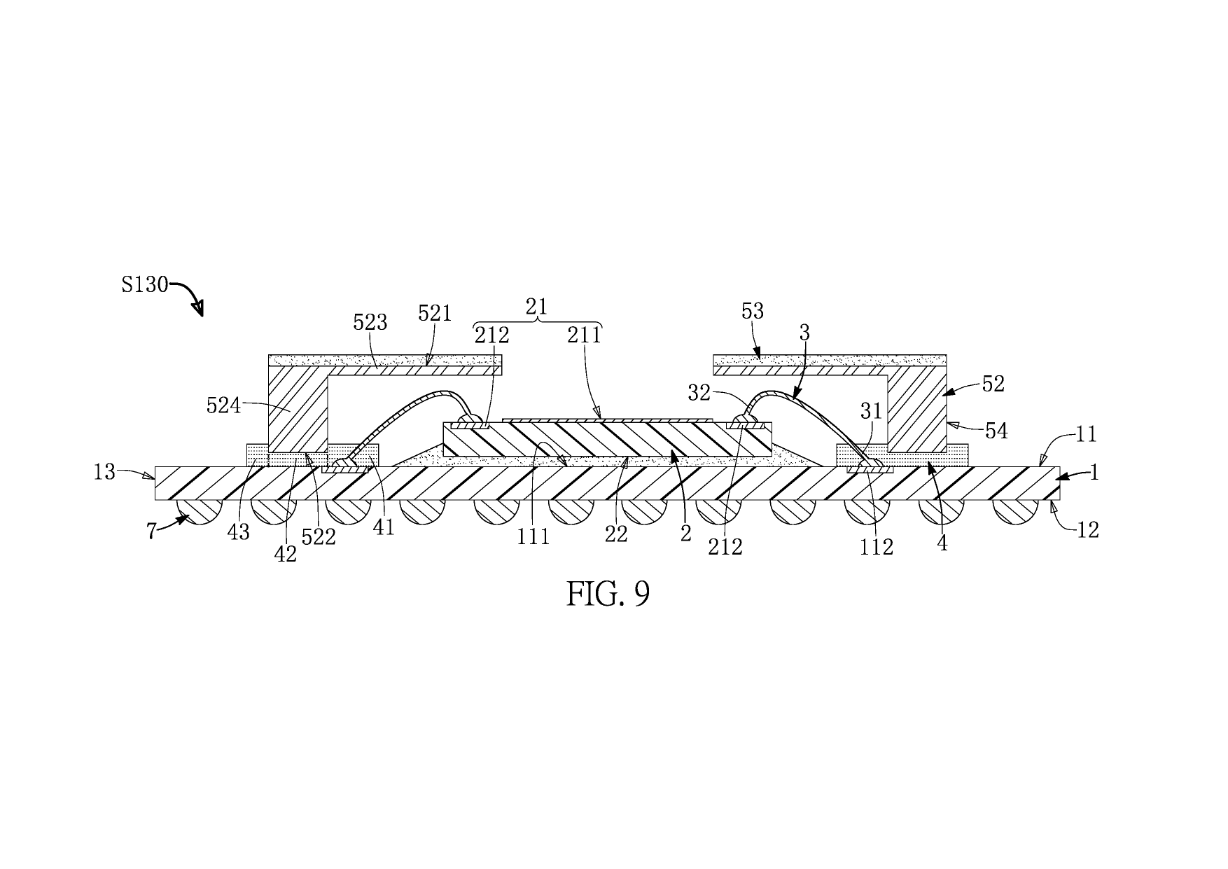

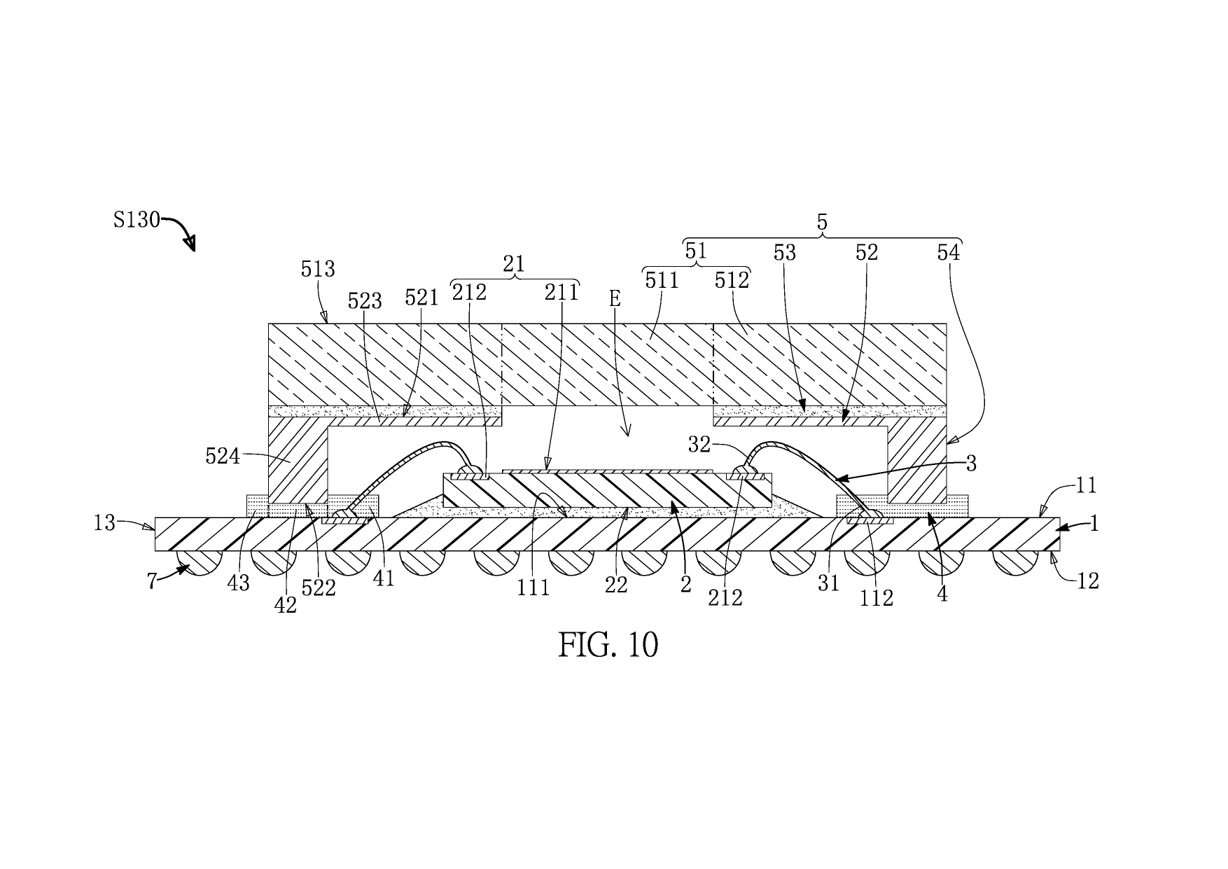

As shown in FIG. 9 and FIG. 10, the placing step S130 is implemented by bonding a cap 5 to the carrying segment 42 and solidifying the adhesive layer 4. The cap 5 includes a light-permeable layer 51 and an opaque stand 52. The light-permeable layer 51 has a light-permeable region 511 facing toward the sensor chip 2 and a distribution region 512 that surrounds the light-permeable region 511. A top side 521 of the opaque stand 52 is fixed to the distribution region 512 of the light-permeable layer 51, and a bottom side 522 of the opaque stand 52 is sunk into and adhered to the carrying segment 42 of the adhesive layer 4.

Specifically, in the placing step S130 of the present embodiment, the opaque stand 52 is adhered to the carrying segment 42 of the adhesive layer 4 through the bottom side 522 thereof, and then the distribution region 512 of the light-permeable layer 51 is adhered to the top side 521 of the opaque stand 52 through a bonding layer 53, but the present disclosure is not limited thereto.

For example, the distribution region 512 of the light-permeable layer 51 can be adhered to the top side 521 of the opaque stand 52 through the bonding layer 53 so as to be jointly formed as the cap 5 before the placing step S130 is implemented, and then the cap 5 is used in the placing step S130. Or, before the placing step S130, the opaque stand 52 can be formed on the distribution region 512 of the light-permeable layer 5 in an injection molding manner so as to be jointly formed as the cap 5, and then the cap 5 is used in the placing step S130.

In addition, the opaque stand 52 includes a shielding board 523 and a ring-shaped frame 524 that is connected to the shielding board 523. The shielding board 523 has the top side 521 of the opaque stand 52, the ring-shaped frame 524 has the bottom side 522 of the opaque stand 52, and the metal wires 3 are arranged in a projection space that is defined by orthogonally projecting the shielding board 523 onto the circuit board 1.

As shown in FIG. 3, the encapsulating step S140 is implemented by forming an encapsulant 6 on the circuit board 1, and the encapsulant 6 covers a surrounding lateral surface 54 of the cap 5. Moreover, the outer segment 43 of the adhesive layer 4 is embedded in the encapsulant 6, and an outer surface 513 of the light-permeable layer 51 is at least partially exposed from the encapsulant 6.

### Beneficial Effects of the Embodiment

In conclusion, the sensor package structure and the manufacturing method thereof in the present disclosure are provided by using the viscosity of the adhesive layer for enabling the adhesive layer to be in suitable structural cooperation with the metal wires and the cap, thereby effectively reducing an overall size of the sensor package structure. Accordingly, the sensor packaging structure provided by the present disclosure can meet the requirements of miniaturization and can prevent the sensor chip from being contaminated by any adhesive.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A manufacturing method of a sensor package structure, comprising:
a preparation step implemented by mounting a sensor chip onto a circuit board and wire-bonding the sensor chip and the circuit board through a plurality of metal wires, wherein each of the metal wires has an outer end portion connected to the circuit board and an inner end portion that is connected to the sensor chip;
an adhesive arrangement step implemented by forming an adhesive layer on the circuit board along the outer end portions of the metal wires, wherein the adhesive layer is ring-shaped and has:
a protecting segment, wherein the outer end portions of the metal wires are embedded in the protecting segment; and
a carrying segment that surrounds the protecting segment;
a placing step implemented by bonding a cap to the carrying segment and solidifying the adhesive layer, wherein the cap includes:
a light-permeable layer having a light-permeable region facing toward the sensor chip and a distribution region that surrounds the light-permeable region; and
an opaque stand having a top side that is fixed to the distribution region of the light-permeable layer, wherein a bottom side of the opaque stand is sunk into and adhered to the carrying segment of the adhesive layer; and
an encapsulating step implemented by forming an encapsulant on the circuit board, wherein the encapsulant covers a surrounding lateral surface of the cap.

2. The manufacturing method according to claim 1, wherein, in the placing strep, after the bottom side of the opaque stand is sunk into and adhered to the carrying segment of the adhesive layer, the distribution region of the light-permeable layer is adhered to the top side of the opaque stand through a bonding layer.

3. The manufacturing method according to claim 1, wherein, before the placing step, the distribution region of the light-permeable layer is adhered to the top side of the opaque stand through a bonding layer.

4. The manufacturing method according to claim 1, wherein, before the placing step, the opaque stand is formed on the distribution region of the light-permeable layer in an injection molding manner so as to be jointly formed as the cap.

5. The manufacturing method according to claim 1, wherein the opaque stand includes:
a shielding board having the top side of the opaque stand, wherein the metal wires are arranged in a projection space that is defined by orthogonally projecting the shielding board onto the circuit board; and
a ring-shaped frame connected to the shielding board and including the bottom side of the opaque stand.

6. The manufacturing method according to claim 1, wherein the adhesive layer has an outer segment that is ring-shaped and that surrounds the carrying segment, and wherein, in the encapsulating step, the outer segment is embedded in the encapsulant.

7. The manufacturing method according to claim 1, wherein a height of the adhesive layer with respect to the circuit board is lower than a height of the sensor chip with respect to the circuit board, and the adhesive layer is not in contact with the sensor chip.

8. A sensor package structure, comprising:
a circuit board having a first surface and a second surface that is opposite to the first surface, wherein the circuit board includes a plurality of bonding pads arranged on the first surface;
a sensor chip mounted on the first surface of the circuit board, wherein a top surface of the sensor chip has a sensing region and a plurality of connection pads that are arranged outside of the sensing region;
a plurality of metal wires each having an outer end portion and an inner end portion, wherein the outer end portions of the metal wires are respectively connected to the bonding pads of the circuit boards, and the inner end portions of the metal wires are respectively connected to the connection pads of the sensor chip;
an adhesive layer being ring-shaped and being disposed on the first surface of the circuit board along the outer end portions of the metal wires, wherein the adhesive layer includes:
a protecting segment, wherein the outer end portions of the metal wires are embedded in the protecting segment; and
a carrying segment that surrounds the protecting segment;
a cap adhered to the carrying segment of the adhesive layer, wherein the cap, the circuit board, and the adhesive layer jointly define an enclosed space, and wherein the cap includes:
a light-permeable layer having a light-permeable region facing toward the sensing region and a distribution region that surrounds the light-permeable region; and
an opaque stand having a top side that is fixed to the distribution region of the light-permeable layer, wherein a bottom side of the opaque stand is sunk into and adhered to the carrying segment of the adhesive layer; and
an encapsulant formed on the first surface of the circuit board, wherein the cap and the adhesive layer are embedded in the encapsulant, and an outer surface of the light-permeable layer is at least partially exposed from the encapsulant.

9. The sensor package structure according to claim 8, wherein the opaque stand includes:
a shielding board having the top side of the opaque stand, wherein the metal wires are arranged in a projection space that is defined by orthogonally projecting the shielding board onto the circuit board; and
a ring-shaped frame connected to the shielding board and having the bottom side of the opaque stand.

10. The sensor package structure according to claim 9, wherein the opaque stand includes a structural reinforcement portion that is connected to the shielding board and the ring-shaped frame and that is arranged inside of the shielding board and the ring-shaped frame.

11. The sensor package structure according to claim 8, wherein the cap includes a bonding layer sandwiched between and adhered to the distribution region of the light-permeable layer and the opaque stand.

12. The sensor package structure according to claim 8, wherein the opaque stand is formed on the distribution region of the light-permeable layer in an injection molding manner so as to be jointly formed as the cap.

13. The sensor package structure according to claim 8, wherein the adhesive layer has an outer segment that is ring-shaped and that surrounds the carrying segment, and wherein the outer segment protrudes from the opaque stand and is embedded in the encapsulant.

14. The sensor package structure according to claim 8, wherein a thickness of the carrying segment is less than a thickness of the protecting segment.

15. The sensor package structure according to claim 8, wherein a height of the adhesive layer with respect to the circuit board is lower than a height of the sensor chip with respect to the circuit board, and the adhesive layer is not in contact with the sensor chip.
